(19) United States
(12) Patent Application Publication
(10) Pub. No.: US 2025/0113669 A1
(43) Pub. Date: Apr. 3, 2025

(54) NITRIDE SEMICONDUCTOR LIGHT-EMITTING ELEMENT

(71) Applicant: Nuvoton Technology Corporation Japan, Kyoto (JP)

(72) Inventors: Takahiro OKAGUCHI, Toyama (JP); Toru TAKAYAMA, Toyama (JP); Shinji YOSHIDA, Shiga (JP)

(21) Appl. No.: 18/975,584

(22) Filed: Dec. 10, 2024

Related U.S. Application Data
(63) Continuation of application No. PCT/JP2023/021208, filed on Jun. 7, 2023.

(30) Foreign Application Priority Data
Jun. 13, 2022 (JP) 2022-095006

(51) Int. Cl. H10H 20/825; H10H 20/80; H10H 20/816; H10H 20/832

(52) U.S. Cl. CPC H10H 20/8252; H10H 20/8162; H10H 20/835; H10H 20/872

(57) ABSTRACT

A nitride semiconductor light-emitting element includes an N-type cladding layer, an N-side guide layer, an active layer, a P-type cladding layer, and a P-side guide layer (an upper P-side guide layer) and an electron blocking layer that are disposed between the active layer and the P-type cladding layer. The N-type cladding layer, the N-side guide layer, the P-side guide layer, the electron blocking layer, and the P-type cladding layer contains Al. The active layer includes an N-side barrier layer, a well layer disposed above the N-side barrier layer, and a P-side barrier layer disposed above the well layer. The average band gap energy of the P-side barrier layer is greater than the average band gap energy of the N-side barrier layer. A thickness of the P-side barrier layer is less than a thickness of the N-side barrier layer.

### CROSS REFERENCE TO RELATED APPLICATIONS

This is a continuation application of PCT International Application No. PCT/JP2023/021208 filed on Jun. 7, 2023, designating the United States of America, which is based on and claims priority of Japanese Patent Application No. 2022-095006 filed on Jun. 13, 2022. The entire disclosures of the above-identified applications, including the specifications, drawings, and claims are incorporated herein by reference in their entirety.

### FIELD

The present disclosure relates to a nitride semiconductor light-emitting element.

### BACKGROUND

Nitride semiconductor light-emitting elements that emit light such as ultraviolet light are conventionally known (see, for example, Patent Literature (PTL) 1). For example, when a watt-class ultraviolet laser light source can be realized using a nitride semiconductor light-emitting element, such a light source can be used as, for example, an exposure light source or a processing light source.

### CITATION LIST

### Patent Literature

PTL 1: Japanese Unexamined Patent Application Publication No. 2010-258363

### SUMMARY

### Technical Problem

An active layer including a quantum well structure, for example, is used as the light-emitting layer of a nitride semiconductor light-emitting element that emits ultraviolet light. Such an active layer includes one or more well layers and a plurality of barrier layers. Since ultraviolet light has a shorter wavelength (i.e., greater energy) than visible light, the band gap energy of a well layer that emits ultraviolet light is greater than the band gap energy of a well layer that emits visible light. For this reason, the difference between the conduction band potential energy and the electron quantum level energy of the barrier layer decreases. In such cases, since electrons are likely to leak from the well layer into the P-side guide layer beyond the barrier layer, the operating carrier density (i.e., the carrier density when the nitride semiconductor light-emitting element is in operation) in the well layer increases.

For example, when a nitride semiconductor light-emitting element is implemented as a laser element including a ridge that is a current injection region, the amplification gain of the well layer in the current injection region increases with an increase in operating carrier density. However, the refractive index of the well layer decreases with an increase in amplification gain in the well layer, based on the relation between the real part and the imaginary part of a complex refractive index of the well layer in the current injection region (corresponding to the Kramers-Kronig relation). In addition, the refractive index of the well layer in the current injection region decreases with an increase in carrier density of the well layer in the current injection region due to a plasma effect. As a result, the effective refractive index of the current injection region can be lower than the effective refractive index outside the current injection region. In this case, a waveguide structure for laser light that propagates through a waveguide including the ridge of the laser element becomes a gain-guided and index antiguided waveguide structure. As a result, the proportion of the portion of laser light that propagates through the outside of the current injection region of the well layer increases, and absorption loss in the well layer increases. Accordingly, the oscillation threshold current value of the laser element increases, and the maximum output power decreases due to the thermal saturation level effect. In other words, the temperature characteristics of the laser element deteriorate.

The present disclosure has been conceived to overcome such a problem, and has an object to provide a nitride semiconductor light-emitting element having superior temperature characteristics.

### Solution to Problem

In order to overcome the above problem, a nitride semiconductor light-emitting element according to one aspect of the present disclosure includes an N-type cladding layer, an N-side guide layer disposed above the N-type cladding layer, an active layer disposed above the N-side guide layer, a P-type cladding layer disposed above the active layer, and a P-side guide layer and an electron blocking layer that are disposed between the active layer and the P-type cladding layer. The N-type cladding layer, the N-side guide layer, the P-side guide layer, the electron blocking layer, and the P-type cladding layer contains Al. The active layer includes an N-side barrier layer, a well layer disposed above the N-side barrier layer, and a P-side barrier layer disposed above the well layer. The average band gap energy of the P-side barrier layer is greater than the average band gap energy of the N-side barrier layer, and the thickness of the P-side barrier layer is less than the thickness of the N-side barrier layer.

### Advantageous Effects

The present disclosure provides a nitride semiconductor light-emitting element having superior temperature characteristics.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic plan view of the overall configuration of a nitride semiconductor light-emitting element according to Embodiment 1.

FIG. 2A is a schematic cross-sectional view of the overall configuration of the nitride semiconductor light-emitting element according to Embodiment 1.

FIG. 2B is a schematic cross-sectional view of the configuration of an active layer included in the nitride semiconductor light-emitting element according to Embodiment 1.

FIG. 3 is a graph illustrating a band gap energy distribution and a refractive index distribution in the stacking direction, in a well layer and a barrier layer of a semiconductor light-emitting element in a wavelength range including 405 nm.

FIG. 4 is a graph illustrating a band gap energy distribution and a refractive index distribution in the stacking direction, in a well layer and a barrier layer of a semiconductor light-emitting element in a wavelength range including 375 nm.

FIG. 5 is a graph illustrating an effective refractive index distribution and a gain distribution of a semiconductor light-emitting element in a wavelength range including 375 nm, in the horizontal direction.

FIG. 6 is a graph illustrating a horizontal far-field pattern of a conventional ultraviolet semiconductor light-emitting element.

FIG. 7 is a graph schematically illustrating a light intensity distribution, a band gap energy distribution, and an impurity concentration distribution of a semiconductor stack according to a comparative example, in the stacking direction.

FIG. 8 is a graph schematically illustrating a light intensity distribution, a band gap energy distribution, and an impurity concentration distribution of a semiconductor stack according to Embodiment 1.

FIG. 9 is a graph illustrating the relation between the optical confinement factor of the nitride semiconductor light-emitting element and the thickness of the P-side barrier layer.

FIG. 10 is a graph illustrating the relation between effective refractive index difference ΔN of the nitride semiconductor light-emitting element and the thickness of the P-side barrier layer.

FIG. 11 is a graph illustrating the relation between the waveguide loss of the nitride semiconductor light-emitting element and the thickness of the P-side barrier layer.

FIG. 12 is a graph illustrating the relation between the peak position of the light intensity distribution in the stacking direction of the nitride semiconductor light-emitting element and the thickness of the P-side barrier layer.

FIG. 13 is a graph illustrating the coordinates of positions in the stacking direction of the nitride semiconductor light-emitting element.

FIG. 14 is a graph schematically illustrating a band gap energy distribution of a semiconductor stack of a nitride semiconductor light-emitting element according to Variation 1 of Embodiment 1.

FIG. 15 is a graph schematically illustrating a band gap energy distribution of a semiconductor stack of a nitride semiconductor light-emitting element according to Variation 2 of Embodiment 1.

FIG. 16 is a schematic cross-sectional view of the overall configuration of a nitride semiconductor light-emitting element according to Embodiment 2.

FIG. 17 is a graph schematically illustrating a band gap energy distribution of a semiconductor stack of the nitride semiconductor light-emitting element according to Embodiment 2.

FIG. 18 is a graph schematically illustrating a band gap energy distribution of a semiconductor stack of a nitride semiconductor light-emitting element according to Variation 1 of Embodiment 2.

FIG. 19 is a graph schematically illustrating a band gap energy distribution of a semiconductor stack of a nitride semiconductor light-emitting element according to Variation 2 of Embodiment 2.

FIG. 20 is a schematic cross-sectional view of the overall configuration of a nitride semiconductor light-emitting element according to Embodiment 3.

FIG. 21 is a graph schematically illustrating a band gap energy distribution of a semiconductor stack of the nitride semiconductor light-emitting element according to Embodiment 3.

FIG. 22 is a graph schematically illustrating a band gap energy distribution of a semiconductor stack of a nitride semiconductor light-emitting element according to Variation 1 of Embodiment 3.

FIG. 23 is a graph schematically illustrating a band gap energy distribution of a semiconductor stack of a nitride semiconductor light-emitting element according to Variation 2 of Embodiment 3.

### DESCRIPTION OF EMBODIMENTS

Hereinafter, embodiments of the present disclosure are described with reference to the drawings. Note that the embodiments described below each show a specific example of the present disclosure. Accordingly, the numerical values, shapes, materials, constituent elements, the arrangement and connection of the constituent elements, etc. indicated in the following embodiments are mere examples, and are not intended to limit the present disclosure.

Moreover, the drawings are schematic drawings and are not necessarily precise illustrations. Accordingly, the figures are not necessarily to scale etc. Note that in the drawings, the same reference signs are assigned to elements that are essentially the same, and overlapping descriptions thereof are omitted or simplified.

Furthermore, in this Specification, the terms “above” and “below” do not refer to the upward (vertically upward) direction and downward (vertically downward) direction in terms of absolute spatial recognition, and are used as terms defined by relative positional relationships based on the stacking order of a stacked configuration. In addition, the terms “above” and “below” are applied not only when two constituent elements are arranged at intervals without another constituent element located between the two constituent elements, but also when two constituent elements are arranged adjacent to each other.

### Embodiment 1

First, a nitride semiconductor light-emitting element according to Embodiment 1 will be described.

### [1-1. Overall Configuration]

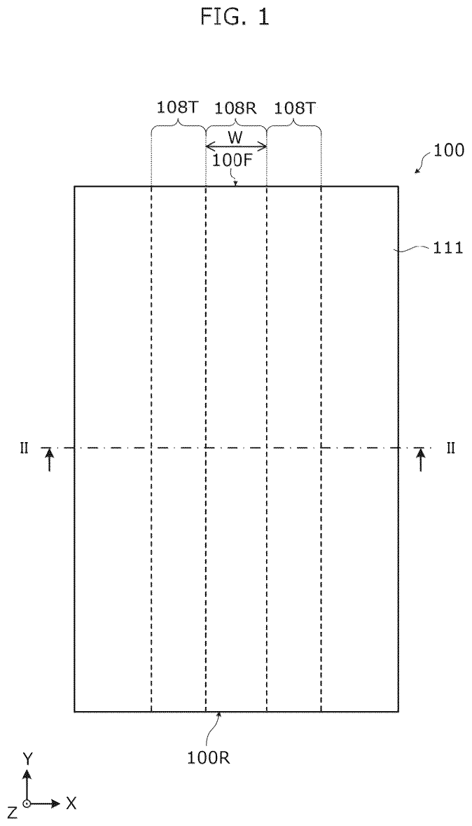

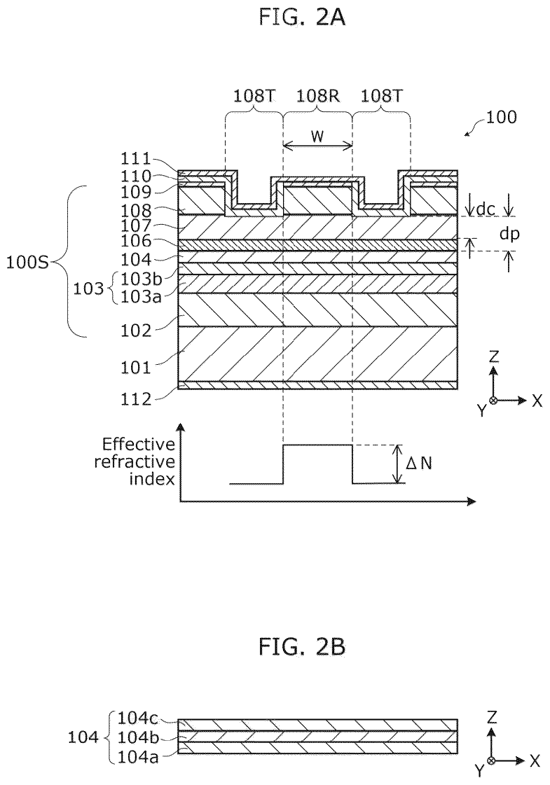

First, the overall configuration of the nitride semiconductor light-emitting element according to the present embodiment will be described with reference to FIG. 1, FIG. 2A, and FIG. 2B. FIG. 1 and FIG. 2A are respectively a schematic plan view and a schematic cross-sectional view of the overall configuration of nitride semiconductor light-emitting element 100 according to the present embodiment. FIG. 2A illustrates a cross section taken along line II-II in FIG. 1. FIG. 2B is a schematic cross-sectional view illustrating the configuration of active layer 104 included in nitride semiconductor light-emitting element 100 according to the present embodiment. Each of the figures illustrates an X-axis, a Y-axis, and a Z-axis that are orthogonal to each other. The X-axis, the Y-axis, and the Z-axis constitute a right-handed orthogonal coordinate system. The stacking direction of nitride semiconductor light-emitting element 100 is parallel to the Z-axis direction, and the main emission direction of light (laser light) is parallel to the Y-axis direction.

Nitride semiconductor light-emitting element 100 includes semiconductor stack 100S including nitride semiconductor layers as illustrated in FIG. 2A, and emits light through end facet 100F (see FIG. 1) in a direction perpendicular to the stacking direction of semiconductor stack 100S (i.e., the Z-axis direction). In the present embodiment, nitride semiconductor light-emitting element 100 is a semiconductor laser element that includes two end facets 100F and 100R that constitute a resonator. End facet 100F is a front end facet through which laser light is emitted, and end facet 100R is a rear end facet that has a higher reflectance than end facet 100F. Nitride semiconductor light-emitting element 100 includes a waveguide provided between end facet 100F and end facet 100R. In the present embodiment, end facet 100F has a reflectance of greater than or equal to 5% and less than or equal to 30%, and end facet 100R has a reflectance of greater than or equal to 95%. The resonator length of nitride semiconductor light-emitting element 100 according to the present embodiment (i.e., the distance between end facet 100F and end facet 100R) is greater than or equal to 500 μm and less than or equal to 2000 μm. Nitride semiconductor light-emitting element 100 emits, for example, ultraviolet light that has a peak wavelength in a wavelength range including 375 nm. Note that nitride semiconductor light-emitting element 100 may emit ultraviolet light that has a peak wavelength in a band other than the wavelength range including 375 nm, or emit light having a peak wavelength in a wavelength range other than ultraviolet light.

As illustrated in FIG. 2A, nitride semiconductor light-emitting element 100 includes substrate 101, semiconductor stack 100S, current blocking layer 110, P-side electrode 111, and N-side electrode 112. Semiconductor stack 100S includes N-type cladding layer 102, N-side guide layer 103, active layer 104, electron blocking layer 106, upper P-side guide layer 107, P-type cladding layer 108, and contact layer 109.

Substrate 101 is a plate-shaped component that serves as a base for nitride semiconductor light-emitting element 100. In the present embodiment, substrate 101 is disposed below N-type cladding layer 102 and contains N-type GaN. More specifically, substrate 101 is a GaN substrate that is doped with Si at an average concentration of 1×10¹⁸ cm⁻³ and has a thickness of 85 μm.

N-type cladding layer 102 is an N-type nitride semiconductor layer that is disposed above substrate 101. N-type cladding layer 102 has a lower average refractive index and a greater average band gap energy than active layer 104. In the present embodiment, N-type cladding layer 102 contains Al. More specifically, N-type cladding layer 102 is an N-type Al_{0.065}Ga_{0.935}N layer that has a thickness of 800 nm. N-type cladding layer 102 is doped with Si as an impurity at an average concentration of 1×10¹⁸ cm⁻³.

In the present disclosure, the average band gap energy of a layer refers to a band gap energy value that is obtained by (i) integrating, in the stacking direction of that layer, the amount of band gap energy at a position in the stacking direction, from the position of an interface on a substrate side to the position of an interface farther from a substrate in the stacking direction and (ii) dividing the integrated amount of the band gap energy by the thickness of that layer (the distance between the interface on the substrate side and the interface farther from the substrate).

The average refractive index of a layer refers to a refractive index value that is obtained by (i) integrating, in the stacking direction of that layer, the magnitude of a refractive index at a position in the stacking direction, from the position of an interface on a substrate side to the position of an interface farther from a substrate in the stacking direction and (ii) dividing the integrated magnitude of the refractive indexes by the thickness of that layer (a distance between the interface on the substrate side and the interface farther from the substrate).

The average impurity concentration of a layer refers to an average impurity concentration value that is obtained by (i) integrating, in the stacking direction of that layer, the magnitude of an impurity concentration at a position in the stacking direction, from the position of an interface on a substrate side to the position of an interface farther from a substrate in the stacking direction and (ii) dividing the integrated magnitude of the impurity concentrations by the thickness of that layer (a distance between the interface on the substrate side and the interface farther from a substrate). In regard to an N-type semiconductor layer, impurities refer to impurities used for doping to achieve an N conductivity type. In regard to a P-type semiconductor layer, impurities refer to impurities used for doping to achieve a P conductivity type.

N-side guide layer 103 is a light guide layer that is disposed above N-type cladding layer 102 and includes a nitride semiconductor. N-side guide layer 103 has a higher average refractive index and a lower average band gap energy than N-type cladding layer 102. N-side guide layer 103 contains Al.

As illustrated in FIG. 2A, in the present embodiment, N-side guide layer 103 includes first N-side guide layer 103a and second N-side guide layer 103b that is disposed above first N-side guide layer 103a. First N-side guide layer 103a is an N-type Al_{0.03}Ga_{0.97}N layer that has a thickness of 127 nm. First N-side guide layer 103a is doped with Si as an N-type impurity at an average concentration of 1×10¹⁸ cm⁻³. Second N-side guide layer 103b is an undoped Al_{0.03}Ga_{0.97}N layer that has a thickness of 60 nm. The average N-type impurity concentration of second N-side guide layer 103b is less than or equal to 1×10¹⁸ cm⁻³. Note that hereinafter, the N-type impurity concentration in each N-side layer and the P-type impurity concentration in each P-side layer are each also simply referred to as “impurity concentration”.

Active layer 104 is a light-emitting layer that is disposed above N-side guide layer 103 and includes a nitride semiconductor. In the present embodiment, active layer 104 has a quantum well structure and emits ultraviolet light. More specifically, as illustrated in FIG. 2B, active layer 104 includes N-side barrier layer 104a, well layer 104b disposed above N-side barrier layer 104a, and P-side barrier layer 104c disposed above well layer 104b. N-side barrier layer 104a and P-side barrier layer 104c are each a nitride semiconductor layer that is disposed above N-side guide layer 103 and serves as a barrier for the quantum well structure. Well layer 104b is a nitride semiconductor layer that serves as a well in the quantum well structure. The average band gap energy of P-side barrier layer 104c is greater than the average band gap energy of N-side barrier layer 104a, and the thickness of P-side barrier layer 104c is less than the thickness of N-side barrier layer 104a.

The average band gap energy of N-side barrier layer 104a is less than the average band gap energy of N-type cladding layer 102. Stated differently, the average refractive index of N-side barrier layer 104a is greater than the average refractive index of N-type cladding layer 102. Accordingly, it is possible to inhibit the peak of a light intensity distribution in the stacking direction from shifting in the direction from active layer 104 toward N-type cladding layer 102.

In the present embodiment, N-side barrier layer 104a is an undoped Al_{0.04}Ga_{0.96}N layer that has a thickness of 18 nm. Well layer 104b is an undoped In_{0.01}Ga_{0.99}N layer that has a thickness of 17.5 nm. P-side barrier layer 104c is an undoped Al_{0.12}Ga_{0.88}N layer that has a thickness of 10 nm.

Electron blocking layer 106 is a nitride semiconductor layer that is disposed between active layer 104 and P-type cladding layer 108. The average band gap energy of electron blocking layer 106 is greater than the average band gap energy of P-side barrier layer 104c. This makes it possible to inhibit electrons from leaking from active layer 104 into P-type cladding layer 108. Electron blocking layer 106 contains Al. In the present embodiment, the average band gap energy of electron blocking layer 106 is greater than the average band gap energy of P-type cladding layer 108. Electron blocking layer 106 is a P-type Al_{0.36}Ga_{0.64}N layer that has a thickness of 5 nm. Electron blocking layer 106 is doped with Mg as a P-type impurity at an average concentration of 1×10¹⁹ cm⁻³.

Upper P-side guide layer 107 is one example of a light guide layer included in the P-side guide layer disposed between active layer 104 and P-type cladding layer 108. Upper P-side guide layer 107 is a nitride semiconductor layer containing Al. In the present embodiment, the light guide layer includes upper P-side guide layer 107 disposed above electron blocking layer 106. The average band gap energy of upper P-side guide layer 107 is less than the average band gap energy of P-type cladding layer 108. The average refractive index of upper P-side guide layer 107 is greater than the average refractive index of P-type cladding layer 108. Upper P-side guide layer 107 is a P-type Al_{0.03}Ga_{0.97}N layer that has a thickness of 40 nm. Upper P-side guide layer 107 is doped with Mg as a P-type impurity, and the Mg concentration in upper P-side guide layer 107 decreases as proximity to P-type cladding layer 108 increases. The Mg concentration in the vicinity of the interface, of upper P-side guide layer 107, that is closer to electron blocking layer 106 is 4×10¹⁸ cm⁻³, and the Mg concentration in the vicinity of the interface, of upper P-side guide layer 107, that is closer to P-type cladding layer 108 is 3.2×10¹⁸ cm⁻³.

P-type cladding layer 108 is a P-type nitride semiconductor layer that is disposed above active layer 104. P-type cladding layer 108 has a lower average refractive index and a greater average band gap energy than active layer 104. P-type cladding layer 108 contains Al. In the present embodiment, P-type cladding layer 108 is disposed above upper P-side guide layer 107. P-type cladding layer 108 is a P-type Al_{0.065}Ga_{0.935}N layer that has a thickness of 450 nm. P-type cladding layer 108 is doped with Mg as a P-type impurity. P-type cladding layer 108 includes a first region having a thickness of 60 nm, a second region having a thickness of 180 nm and positioned above the first region, a third region having a thickness of 100 nm and positioned above the second region, and a fourth region having a thickness of 110 nm and positioned above the third region. In the first region, the Mg concentration decreases from 3.2×10¹⁸ cm⁻³ to 2.0×10¹⁸ cm⁻³ as distance from active layer 104 increases. In the second region, the Mg concentration is constant at 2.0×10¹⁸ cm⁻³. In the third region, the Mg concentration increases from 2.0×10¹⁸ cm⁻³ to 1.0×10¹⁹ cm⁻³ as distance from active layer 104 increases. In the fourth region, the Mg concentration is constant at 1.0×10¹⁹ cm⁻³.

Ridge 108R is provided in P-type cladding layer 108, as illustrated in FIG. 1 and FIG. 2A. Additionally, two trenches 108T that extend along ridge 108R in the Y-axis direction are provided in P-type cladding layer 108. In the present embodiment, ridge width W is approximately 30 μm. Moreover, as illustrated in FIG. 2A, the distance between the lower end portion of ridge 108R (i.e., the bottom portion of trench 108T) and active layer 104 is denoted by dc. Furthermore, the distance between the lower end portion of ridge 108R and electron blocking layer 106 is denoted by dc.

Contact layer 109 is a nitride semiconductor layer that is disposed above P-type cladding layer 108 and in contact with P-side electrode 111. In the present embodiment, contact layer 109 is a P-type GaN layer having a thickness of 100 nm. Contact layer 109 is doped with Mg as an impurity at an average concentration of 1×10²⁰ cm⁻³.

Current blocking layer 110 is an insulating layer that is disposed above P-type cladding layer 108 and is transmissive to light from active layer 104. Current blocking layer 110 is disposed in a region of the top faces of P-type cladding layer 108 and contact layer 109 other than the top face of ridge 108R. Note that current blocking layer 110 may be disposed in a region of a portion of the top face of ridge 108R. For example, current blocking layer 110 may be disposed in an end edge region of the top face of ridge 108R. In the present embodiment, current blocking layer 110 is an SiO₂ layer.

P-side electrode 111 is a conductive layer that is disposed above P-type cladding layer 108. In the present embodiment, P-side electrode 111 is disposed above contact layer 109 and current blocking layer 110. P-side electrode 111 is, for example, a single-layer film or a multi-layer film that contains at least one of Cr, Ti, Ni, Pd, Pt, Ag, or Au.

Since it is possible to minimize light propagating through a waveguide from leaking to P-side electrode 111 on contact layer 109 by using Ag having a low refractive index for light from the ultraviolet to infrared range for at least a portion of P-side electrode 111, it is possible to reduce waveguide loss that occurs in P-side electrode 111. Ag has a refractive index of at most 0.5 in a wavelength range from at least 325 nm to at most 1500 nm, and has a refractive index of at most 0.2 in a wavelength range from at least 360 nm to at most 950 nm. As a result, in a wide wavelength range from at least 325 nm to at most 950 nm, by including Ag in P-side electrode 111, it is possible to reduce optical loss in P-side electrode 111. In this case, since it is possible to minimize the light propagating through the waveguide from leaking to P-side electrode 111 even if P-type cladding layer 108 has a thickness of at most 0.4 μm, it is possible to inhibit an increase in waveguide loss while reducing series resistance of nitride semiconductor light-emitting element 100. As a result, it is possible to reduce the operating voltage and the operating current.

Here, in order to stably confine light propagating through the waveguide to ridge 108R, as will be described later, it is necessary to form an effective refractive index difference (ΔN) to cause the effective refractive index of an inner region of ridge 108R to be higher than the effective refractive index of an outer region of ridge 108R. Specifically, it is necessary to provide SiO₂ having a lower refractive index than P-type cladding layer 108 in a lateral wall of ridge 108R, and to reduce the effective refractive index of the outer region of ridge 108R. In this case, since a region in which SiO₂ is provided becomes smaller in the thickness direction of the lateral wall of ridge 108R when the thickness of P-type cladding layer 108 is excessively reduced, an effect of reducing the effective refractive index of the outer region of ridge 108R is reduced. For this reason, P-type cladding layer 108 may have a thickness of at least 150 nm.

The thickness of P-type cladding layer 108 may be greater than the total thickness of the P-side light guide layer (in the present embodiment, the thickness of upper P-side guide layer 107), and greater than the total thickness of the N-side light guide layer (in the present embodiment, the thickness of N-side guide layer 103). This gives P-type cladding layer 108 a thickness sufficient enough to confine light below P-side electrode 111, making it possible to inhibit waveguide loss. When P-side electrode 111 includes Ag, the thickness of P-type cladding layer 108 may be, for example, at least 200 nm and at most 400 nm. This makes it possible to reduce the operating voltage and operating current while inhibiting waveguide loss.

Layers with a high Al composition ratio, such as P-type cladding layer 108, have a large strain on substrate 101 containing N-type GaN. Since the total Al content in P-type cladding layer 108 can be reduced by reducing the thickness of P-type cladding layer 108, the strain of P-type cladding layer 108 on substrate 101 can be reduced.

Accordingly, it is possible to inhibit nitride semiconductor light-emitting element 100 from cracking due to strain from P-type cladding layer 108.

The Ag in P-side electrode 111 may, for example, form an ohmic contact with contact layer 109. Stated differently, P-side electrode 111 may include an Ag film that forms an ohmic contact with contact layer 109. This makes it possible to confine light below contact layer 109, further reducing optical loss in P-side electrode 111.

N-side electrode 112 is a conductive layer that is disposed below substrate 101 (i.e., a principal surface opposite to a principal surface of substrate 101 above which N-type cladding layer 102 etc., is disposed). N-side electrode 112 is, for example, a single-layer film or a multi-layer film that contains at least one of Cr, Ti, Ni, Pd, Pt, or Au.

Since nitride semiconductor light-emitting element 100 includes the above-described configuration, as illustrated in FIG. 2A, effective refractive index difference ΔN forms between an inner portion of ridge 108R and an outer portion of ridge 108R (the trench 108T portion). This makes it possible to confine light that is generated in a portion of active layer 104 below ridge 108R to the horizontal direction (i.e., the X-axis direction).

[1-2. Problem with Ultraviolet Semiconductor Light-Emitting Element]

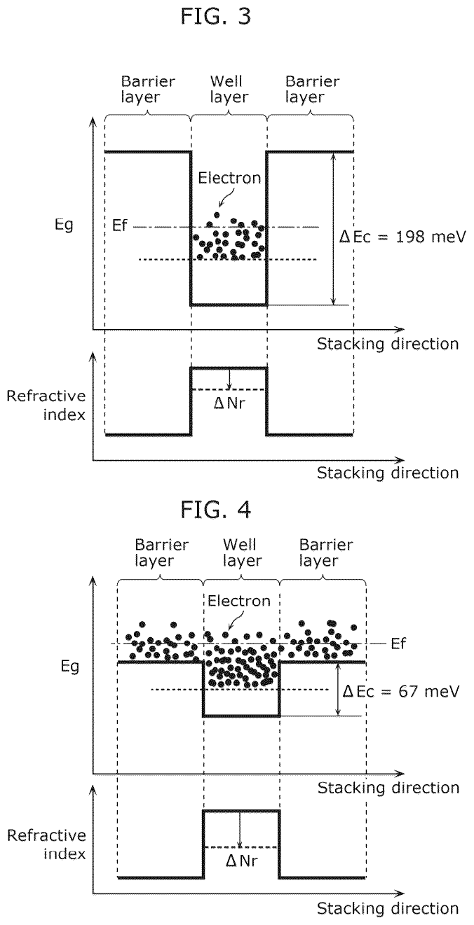

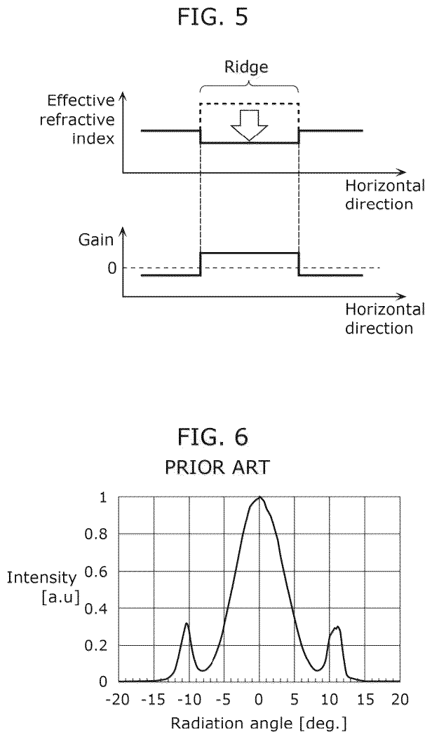

Next, one problem that may occur in an ultraviolet semiconductor light-emitting element described in the Technical Problem section of the present disclosure will be described in detail with reference to FIG. 3 to FIG. 6. FIG. 3 is a graph illustrating a band gap energy (Eg) distribution and a refractive index distribution in the stacking direction, in a well layer and a barrier layer of a semiconductor light-emitting element in a wavelength range including 405 nm that has a longer wavelength than ultraviolet light. FIG. 4 is a graph illustrating a band gap energy (Eg) distribution and a refractive index distribution in the stacking direction, in a well layer and a barrier layer of a semiconductor light-emitting element in a wavelength range including 375 nm that is an ultraviolet region. FIG. 5 is a graph illustrating an effective refractive index distribution and a gain distribution of the semiconductor light-emitting element in the wavelength range including 375 nm, in the horizontal direction (corresponding to the X-axis direction in FIG. 1 to FIG. 2B). FIG. 6 is a graph illustrating a horizontal far-field pattern of a conventional ultraviolet semiconductor light-emitting element. The horizontal axis of FIG. 6 indicates a radiation angle in the horizontal direction, and the vertical axis of the same indicates a light intensity.

As illustrated in FIG. 3, in the semiconductor light-emitting element in the wavelength range including 405 nm, since the band gap energy of the well layer is relatively small, it is possible to set difference ΔEc between the conduction band potential energy and the electron quantum level energy of the barrier layer to be a relatively large value (198 meV). In this case, since Fermi energy Ef of electrons becomes sufficiently smaller than the conduction band potential energy of the barrier layer, it is possible to inhibit the electrons from leaking from the well layer into a P-side semiconductor layer beyond the barrier layer.

In contrast, as illustrated in FIG. 4, in the ultraviolet semiconductor light-emitting element, since the band gap energy of the well layer is relatively large, difference ΔEc between the conduction band potential energy and the electron quantum level energy of the barrier layer is a small value (67 meV). In this case, since Fermi energy Ef of electrons can become larger than the conduction band potential energy of the barrier layer, the electrons are likely to leak from the well layer into a P-side semiconductor layer beyond the barrier layer. Accordingly, since carriers that are incapable of contributing to light emission in the well layer increase, the operating carrier density in the well layer increases.

When the operating carrier density in the well layer increases in this manner, the amplification gain of light in the well layer increases. However, the refractive index of the well layer decreases with an increase in amplification gain in the well layer, based on the relation between the real part and imaginary part of a complex refractive index of the well layer in the current injection region. In addition, the refractive index of the well layer in the current injection region decreases with an increase in carrier density of the well layer in the current injection region due to a plasma effect. As a result, the effective refractive index of the current injection region can be lower than the effective refractive index outside the current injection region. For example, when the semiconductor light-emitting element is a laser element including a ridge and a current is injected into the ridge, as illustrated in FIG. 5, the effective refractive index in the ridge that is a current injection region can be lower than the effective refractive index of the outside of the current injection region.

For this reason, a waveguide structure for laser light that propagates through a waveguide that corresponds to the ridge of the semiconductor light-emitting element becomes a gain-guided and index antiguided waveguide structure. As a result, the proportion of a portion of the laser light that propagates through the outside of the current injection region (a region located below the ridge) in the well layer increases, and peaks as illustrated in FIG. 6 occur in foot portions of the far field pattern of the semiconductor light-emitting element. In this case, since light is absorbed outside the current injection region in the well layer, absorption loss in the well layer increases. Accordingly, the oscillation threshold current value of the semiconductor light-emitting element increases, and the maximum output power decreases due to the thermal saturation effect. In other words, the temperature characteristics of the semiconductor light-emitting element deteriorate. Additionally, a portion that bends non-linearly (what is called a kink) can occur in a graph showing the current-light output (IL) characteristics of the semiconductor light-emitting element. To put it another way, the stability of the light output of the semiconductor light-emitting element deteriorates.

Nitride semiconductor light-emitting element 100 according to the present embodiment overcomes such problems with the ultraviolet semiconductor light-emitting element.

### [1-3. Light Intensity Distribution]

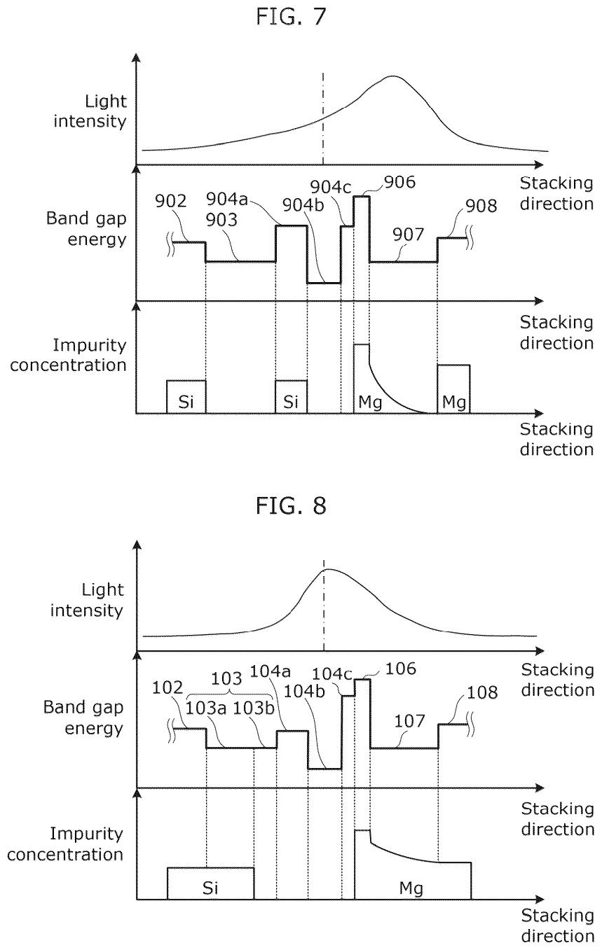

Next, a light intensity distribution of nitride semiconductor light-emitting element 100 according to the present embodiment in the stacking direction will be described in comparison with comparative examples, with reference to FIG. 7 and FIG. 8. FIG. 7 is a graph schematically illustrating a light intensity distribution, a band gap energy distribution, and an impurity concentration distribution of a semiconductor stack according to a comparative example, in the stacking direction. FIG. 8 is a graph schematically illustrating a light intensity distribution, a band gap energy distribution, and an impurity concentration distribution of semiconductor stack 100S according to the present embodiment.

The semiconductor stack according to the comparative example illustrated in FIG. 7 corresponds to the semiconductor stack described in PTL 1. The semiconductor stack according to the comparative example includes N-type cladding layer 902, N-side guide layer 903, active layer (N-side barrier layer 904a, well layer 904b, and P-side barrier layer 904c), electron blocking layer 906, upper P-side guide layer 907, and P-type cladding layer 908. The semiconductor stack according to the comparative example differs from semiconductor stack 100S according to the present embodiment mainly in that the band gap energy of N-side barrier layer 904a is equal to the band gap energy of P-side barrier layer 904c.

In such a semiconductor stack according to the comparative example, when N-type cladding layer 902 and P-type cladding layer 908 contain AlGaN and have the same Al composition ratio, P-type cladding layer 908 has a higher refractive index than N-type cladding layer 902. This is because it is assumed that since the ionization energy of Mg that is a P-type impurity is greater than the ionization energy of Si that is an N-type impurity, it is necessary to set a P-type impurity concentration to be higher than an N-type impurity concentration, and thus a P-type layer that achieves a relatively deep energy level has greater light absorption than an N-type layer, resulting in a higher refractive index. Accordingly, as illustrated in FIG. 7, the peak position of the light intensity distribution is shifted in a direction from the center of well layer 904b of the active layer (see the dash-dot line illustrated in FIG. 7) toward P-type cladding layer 908. As a result, in the semiconductor stack according to the comparative example, the optical confinement factor to the active layer decreases, and the operating carrier density increases. For this reason, the refractive index of well layer 904b decreases.

In semiconductor stack 100S according to the present embodiment, as illustrated in FIG. 8, the average band gap energy of P-side barrier layer 104c is greater than the average band gap energy of N-side barrier layer 104a. Stated differently, the average refractive index of P-side barrier layer 104c is less than the average refractive index of N-side barrier layer 104a. With such a configuration, it is possible to shift the peak position of the light intensity distribution in the stacking direction toward N-side barrier layer 104a. Stated differently, with nitride semiconductor light-emitting element 100 according to the present embodiment, it is possible to improve controllability of the peak position of the light intensity distribution.

By moving the peak position of the light intensity distribution closer to active layer 104 in this manner, that is, by moving the peak position of the light intensity distribution away from upper P-side guide layer 107 and P-type cladding layer 108, it is possible to reduce free carrier loss caused by impurities in upper P-side guide layer 107 and P-type cladding layer 108. For this reason, it is possible to decrease an oscillation threshold current value and improve a thermal saturation level. In other words, it is possible to achieve nitride semiconductor light-emitting element 100 having superior temperature characteristics and high slope efficiency. This allows high-temperature high-light output power operation in nitride semiconductor light-emitting element 100.

In the present embodiment, the thickness of P-side barrier layer 104c is less than the thickness of N-side barrier layer 104a. This makes it possible to reduce the distance from well layer 104b to the lower end of ridge 108R. Stated differently, it is possible to bring the low refractive index region in trench 108T closer to the well layer. This makes it possible to increase effective refractive index difference ΔN. Consequently, it is possible to increase the optical confinement factor of nitride semiconductor light-emitting element 100 to a waveguide. Since this makes it possible to stably confine the horizontal lateral mode of laser light to the waveguide in nitride semiconductor light-emitting element 100, it is possible to inhibit kinks in current-light output characteristics from occurring.

In the present embodiment, the average band gap energy of upper P-side guide layer 107 is less than the average band gap energy of P-type cladding layer 108. Stated differently, the average refractive index of upper P-side guide layer 107 is greater than the average refractive index of P-type cladding layer 108. Accordingly, it is possible to inhibit the peak position of a light intensity distribution in the stacking direction from shifting toward P-type cladding layer 108. Accordingly, it is possible to reduce free carrier loss caused by impurities in P-type cladding layer 108.

In the present embodiment, the average band gap energy of P-side barrier layer 104c is less than the average band gap energy of electron blocking layer 106. Accordingly, it is possible to block electrons moving toward P-type cladding layer 108 beyond P-side barrier layer 104c with electron blocking layer 106, and return the electrons to active layer 104. Accordingly, since it is possible to reduce electrons that do not contribute to light emission and cause heat generation, it is possible to decrease the oscillation threshold current value and improve the thermal saturation level. In other words, it is possible to achieve nitride semiconductor light-emitting element 100 having superior temperature characteristics and high slope efficiency.

### [1-4. Simulation Results]

Next, characteristics of nitride semiconductor light-emitting element 100 according to the present embodiment will be described with reference to simulation results. Note that configurations other than N-side barrier layer 104a, P-side barrier layer 104c, upper P-side guide layer 107, and P-type cladding layer 108 of the nitride semiconductor light-emitting element used in this simulation are the same as those of nitride semiconductor light-emitting element 100 according to the present embodiment described above.

Upper P-side guide layer 107 used in this simulation is a P-type Al_{0.03}Ga_{0.97}N layer that has a thickness of 60 nm. Upper P-side guide layer 107 is doped with Mg as a P-type impurity, and the Mg concentration in upper P-side guide layer 107 decreases as proximity to P-type cladding layer 108 increases. The Mg concentration in the vicinity of the interface, of upper P-side guide layer 107, that is closer to electron blocking layer 106 is 4×10¹⁸ cm⁻³, and the Mg concentration in the vicinity of the interface, of upper P-side guide layer 107, that is closer to P-type cladding layer 108 is 2.8×10¹⁸ cm⁻³.

P-type cladding layer 108 used in this simulation is a P-type Al_{0.065}Ga_{0.935}N layer that has a thickness of 450 nm. P-type cladding layer 108 is doped with Mg as a P-type impurity. P-type cladding layer 108 includes a first region having a thickness of 40 nm, a second region having a thickness of 180 nm and positioned above the first region, a third region having a thickness of 100 nm and positioned above the second region, and a fourth region having a thickness of 130 nm and positioned above the third region. In the first region, the Mg concentration decreases from 2.8×10¹⁸ cm⁻³ to 2.0×10¹⁸ cm⁻³ as distance from active layer 104 increases. In the second region, the Mg concentration is constant at 2.0×10¹⁸ cm⁻³. In the third region, the Mg concentration increases from 2.0×10¹⁸ cm⁻³ to 1.0×10¹⁹ cm⁻³ as distance from active layer 104 increases. In the fourth region, the Mg concentration is constant at 1.0×10¹⁹ cm⁻³.

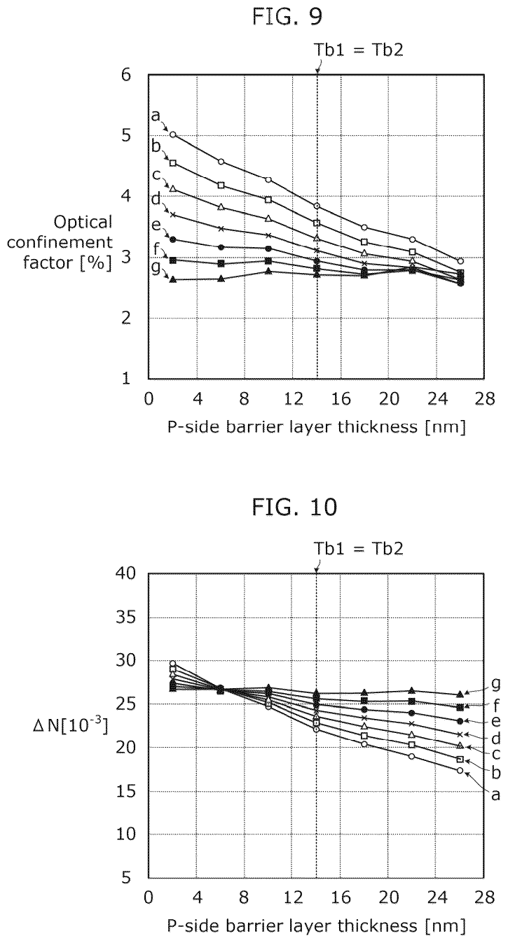

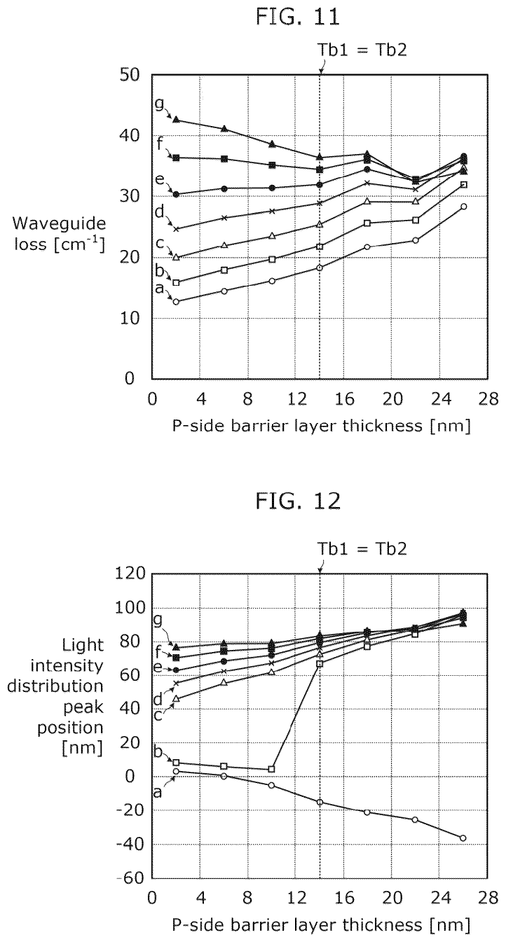

Hereinafter, the optical confinement factor, effective refractive index difference ΔN, waveguide loss, and peak position of light intensity distribution in the stacking direction of the nitride semiconductor light-emitting element will be described with reference to FIG. 9 through FIG. 12. FIG. 9, FIG. 10, FIG. 11, and FIG. 12 are graphs illustrating relations between the optical confinement factor, effective refractive index difference ΔN, waveguide loss, and peak position of light intensity distribution in the stacking direction of the nitride semiconductor light-emitting element, respectively, and the thickness of P-side barrier layer 104c.

In this simulation, the total thickness (Tb1+Tb2) of thickness Tb2 of P-side barrier layer 104c and thickness Tb1 of N-side barrier layer 104a is set to 28 nm. Stated differently, when thickness Tb2 of P-side barrier layer 104c is 2 nm, thickness Tb1 of N-side barrier layer 104a is 26 nm. Stated differently, the left half of the graph in each figure corresponds to when Tb1>Tb2, and the right half corresponds to when Tb1<Tb2.

Each figure shows the relationships when varying Al composition ratio Xb2 of P-side barrier layer 104c and Al composition ratio Xb1 of N-side barrier layer 104a. The curves (broken lines) a shown in each figure indicate the relationship when Xb1=0.02 and Xb2=0.14, curves b indicate the relationship when Xb1=0.04 and Xb2=0.12, curves c indicate the relationship when Xb1=0.06 and Xb2=0.10, curves d indicate the relationship when Xb1=0.08 and Xb2=0.08, curves e indicate the relationship when Xb1=0.10 and Xb2=0.06, curves f indicate the relationship when Xb1=0.12 and Xb2=0.04, and curves g indicate the relationship when Xb1=0.14 and Xb2=0.02.

First, the relationship between the optical confinement factor of the nitride semiconductor light-emitting element and the thickness of P-side barrier layer 104c (and N-side barrier layer 104a) will be described with reference to FIG. 9.

As illustrated in FIG. 9, there is a tendency for the optical confinement factor to increase when thickness Tb2 of P-side barrier layer 104c is smaller than thickness Tb1 of N-side barrier layer 104a, and Al composition ratio Xb2 of P-side barrier layer 104c is greater than Al composition ratio Xb1 of N-side barrier layer 104a (in other words, when the average band gap energy of P-side barrier layer 104c is greater than the average band gap energy of N-side barrier layer 104a). Therefore, as in nitride semiconductor light-emitting element 100 according to the present embodiment, by making the average band gap energy of P-side barrier layer 104c greater than the average band gap energy of N-side barrier layer 104a, and making thickness Tb2 of P-side barrier layer 104c less than thickness Tb1 of N-side barrier layer 104a, it is possible to increase the optical confinement factor.

Next, the relationship between effective refractive index difference ΔN of the nitride semiconductor light-emitting element and the thickness of P-side barrier layer 104c (and N-side barrier layer 104a) will be described with reference to FIG. 10.

As illustrated in FIG. 10, there is a tendency for effective refractive index difference ΔN to increase when thickness Tb2 of P-side barrier layer 104c is smaller than thickness Tb1 of N-side barrier layer 104a, and Al composition ratio Xb2 of P-side barrier layer 104c is greater than Al composition ratio Xb1 of N-side barrier layer 104a. Therefore, as in nitride semiconductor light-emitting element 100 according to the present embodiment, by making the average band gap energy of P-side barrier layer 104c greater than the average band gap energy of N-side barrier layer 104a, and making thickness Tb2 of P-side barrier layer 104c less than thickness Tb1 of N-side barrier layer 104a, it is possible to increase effective refractive index difference ΔN.

Next, the relationship between waveguide loss of the nitride semiconductor light-emitting element and the thickness of P-side barrier layer 104c (and N-side barrier layer 104a) will be described with reference to FIG. 11.

As illustrated in FIG. 11, there is a tendency for waveguide loss to decrease when thickness Tb2 of P-side barrier layer 104c is smaller than thickness Tb1 of N-side barrier layer 104a, and Al composition ratio Xb2 of P-side barrier layer 104c is greater than Al composition ratio Xb1 of N-side barrier layer 104a. Therefore, as in nitride semiconductor light-emitting element 100 according to the present embodiment, by making the average band gap energy of P-side barrier layer 104c greater than the average band gap energy of N-side barrier layer 104a, and making thickness Tb2 of P-side barrier layer 104c less than thickness Tb1 of N-side barrier layer 104a, it is possible to reduce waveguide loss.

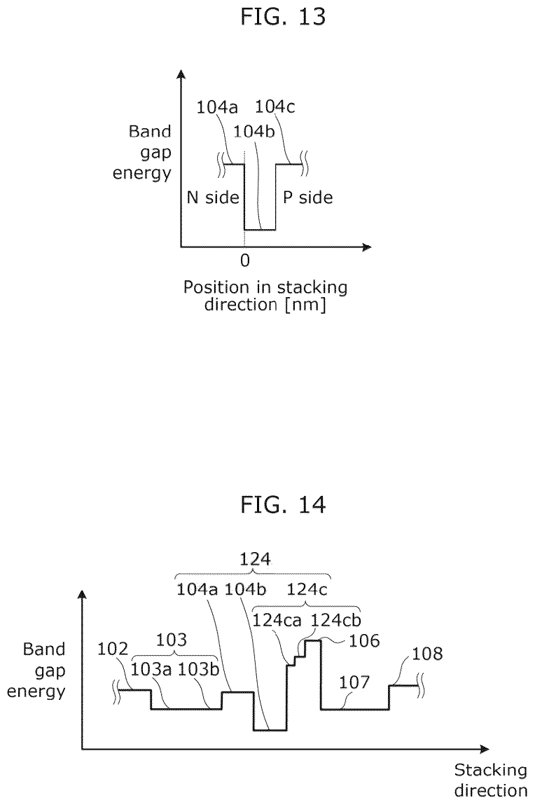

Next, the relationship between the peak position of the light intensity distribution in the stacking direction of the nitride semiconductor light-emitting element and the thickness of P-side barrier layer 104c (and N-side barrier layer 104a) will be described with reference to FIG. 12. Here, positions in the light intensity distribution in the stacking direction will be described with reference to FIG. 13.

FIG. 13 is a graph illustrating the coordinates of positions in the stacking direction of the nitride semiconductor light-emitting element. As illustrated in FIG. 13, the coordinates of the position in the stacking direction of the N-side end face of well layer 104b in active layer 104, that is, the interface between well layer 104b and N-side barrier layer 104a, are zero, with the downward direction (direction toward N-type cladding layer 102) being the negative direction of coordinates and the upward direction (direction toward P-type cladding layer 108) being the positive direction of coordinates.

As illustrated in FIG. 12, there is a tendency for the peak position of the light intensity distribution to approach well layer 104b when thickness Tb2 of P-side barrier layer 104c is smaller than thickness Tb1 of N-side barrier layer 104a, and Al composition ratio Xb2 of P-side barrier layer 104c is greater than Al composition ratio Xb1 of N-side barrier layer 104a. Therefore, as in nitride semiconductor light-emitting element 100 according to the present embodiment, by making the average band gap energy of P-side barrier layer 104c greater than the average band gap energy of N-side barrier layer 104a, and making thickness Tb2 of P-side barrier layer 104c less than thickness Tb1 of N-side barrier layer 104a, it is possible to move the peak position of the light intensity distribution in the stacking direction closer to well layer 104b of active layer 104.

According to the present embodiment, it has been confirmed from simulation results similar to the above simulation that it is possible to achieve nitride semiconductor light-emitting element 100 that has an optical confinement factor of 3.85%, effective refractive index difference ΔN of 22.9×10⁻³, a waveguide loss of 22.8 cm⁻¹, and a peak position of light intensity distribution in the stacking direction of 1.81 nm (i.e., the peak position is within well layer 104b).

### [1-5. Variation 1]

Next, a nitride semiconductor light-emitting element according to Variation 1 of the present embodiment will be described. The nitride semiconductor light-emitting element according to the present variation differs from nitride semiconductor light-emitting element 100 according to the present embodiment in regard to the configuration of the P-side barrier layer, and is identical in the other aspects. Hereinafter, the nitride semiconductor light-emitting element according to the present variation will be described with reference to FIG. 14, focusing mainly on the differences from nitride semiconductor light-emitting element 100 according to the present embodiment. FIG. 14 is a graph schematically illustrating a band gap energy distribution of a semiconductor stack of the nitride semiconductor light-emitting element according to the present variation.

As illustrated in FIG. 14, the semiconductor stack of the nitride semiconductor light-emitting element according to the present variation includes N-type cladding layer 102, N-side guide layer 103, active layer 124, electron blocking layer 106, upper P-side guide layer 107, and P-type cladding layer 108. Although not illustrated in FIG. 14, the semiconductor stack according to the present variation further includes contact layer 109, just like semiconductor stack 100S according to the present embodiment.

As illustrated in FIG. 14, active layer 124 according to the present variation includes N-side barrier layer 104a, well layer 104b, and P-side barrier layer 124c. P-side barrier layer 124c includes first P-side barrier layer 124ca and second P-side barrier layer 124cb that is disposed above first P-side barrier layer 124ca. Note that in the nitride semiconductor light-emitting element according to the present variation having such a configuration, just like P-side barrier layer 104c according to the present embodiment, the average band gap energy of P-side barrier layer 124c is greater than the average band gap energy of N-side barrier layer 104a, and the (total) thickness of P-side barrier layer 124c is less than the thickness of N-side barrier layer 104a.

As illustrated in FIG. 14, the average band gap energy of second P-side barrier layer 124cb is greater than the average band gap energy of first P-side barrier layer 124ca. This makes it possible to reduce the band spike formed between P-side barrier layer 124c and electron blocking layer 106. Accordingly, since it is possible to reduce the electrical resistance of the nitride semiconductor light-emitting element caused by the band spike, it is possible to reduce the operating voltage of the nitride semiconductor light-emitting element.

The average band gap energy of second P-side barrier layer 124cb is less than the average band gap energy of electron blocking layer 106. This makes it possible to inhibit electrons moving from well layer 104b toward upper P-side guide layer 107 from crossing electron blocking layer 106.

First P-side barrier layer 124ca is a nitride semiconductor layer containing Al. First P-side barrier layer 124ca is, for example, an AlGaN layer or an AlInGaN layer. The average impurity concentration of first P-side barrier layer 124ca is less than or equal to 1×10¹⁸ cm⁻³.

Second P-side barrier layer 124cb is a nitride semiconductor layer containing Al. Second P-side barrier layer 124cb is, for example, an AlGaN layer or an AlInGaN layer. The average impurity concentration of second P-side barrier layer 124cb is less than or equal to 1×10¹⁸ cm⁻³. Accordingly, since it is possible to reduce free carrier loss in second P-side barrier layer 124cb, it is possible to reduce the waveguide loss of the nitride semiconductor light-emitting element.

### [1-6. Variation 2]

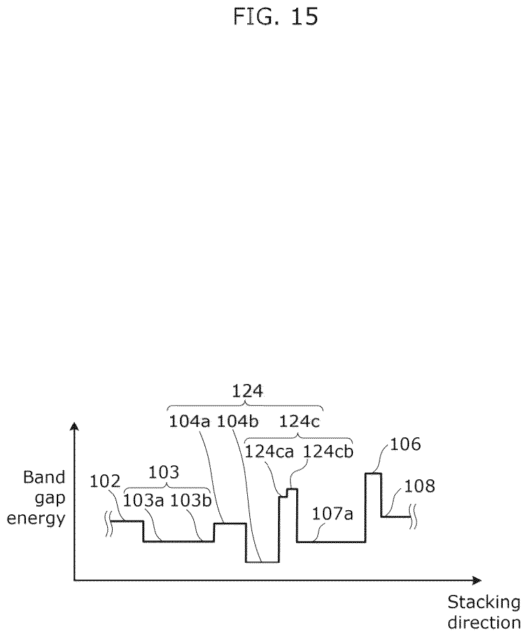

Next, a nitride semiconductor light-emitting element according to Variation 2 of the present embodiment will be described. The nitride semiconductor light-emitting element according to the present variation differs from the nitride semiconductor light-emitting element according to Variation 1 of the present embodiment mainly in regard to the arrangement position (i.e., stacking order) of the electron blocking layer and the upper P-side guide layer. Hereinafter, the nitride semiconductor light-emitting element according to the present variation will be described with reference to FIG. 15, focusing mainly on the differences from the nitride semiconductor light-emitting element according to Variation 1 of the present embodiment. FIG. 15 is a graph schematically illustrating a band gap energy distribution of a semiconductor stack of the nitride semiconductor light-emitting element according to the present variation.

As illustrated in FIG. 15, the semiconductor stack of the nitride semiconductor light-emitting element according to the present variation includes N-type cladding layer 102, N-side guide layer 103, active layer 124, upper P-side guide layer 107a, electron blocking layer 106, and P-type cladding layer 108. Although not illustrated in FIG. 15, the semiconductor stack according to the present variation further includes contact layer 109, just like semiconductor stack 100S according to the present embodiment.

Upper P-side guide layer 107a according to the present variation is one example of a light guide layer included in the P-side guide layer disposed between active layer 104 and P-type cladding layer 108. Upper P-side guide layer 107a is a nitride semiconductor layer containing Al. In the semiconductor stack according to the present variation, upper P-side guide layer 107a is disposed above active layer 124. Electron blocking layer 106 is disposed above upper P-side guide layer 107a. Stated differently, upper P-side guide layer 107a is disposed between active layer 124 and electron blocking layer 106.

The average band gap energy of upper P-side guide layer 107a is less than the average band gap energy of P-type cladding layer 108. The average refractive index of upper P-side guide layer 107a is greater than the average refractive index of P-type cladding layer 108. Upper P-side guide layer 107a is, for example, an AlGaN layer or an AlInGaN layer. The average impurity concentration of upper P-side guide layer 107a is less than or equal to 1×10¹⁸ cm⁻³. Upper P-side guide layer 107a is, for example, a P-type Al_{0.02}Ga_{0.98}N layer that has a thickness of 60 nm.

By arranging upper P-side guide layer 107a, which has a lower Mg concentration than electron blocking layer 106, between electron blocking layer 106 with high Mg concentration and active layer 124, it is possible to reduce the thermal diffusion of Mg into active layer 124. Accordingly, since it is possible to further reduce free carrier loss in active layer 124, it is possible to further reduce the waveguide loss of the nitride semiconductor light-emitting element.

The nitride semiconductor light-emitting element according to the present variation includes P-side electrode 111 disposed above contact layer 109. In the present variation, P-side electrode 111 may contain Ag. More specifically, P-side electrode 111 may include an Ag film that forms an ohmic contact with contact layer 109. By including such P-side electrode 111 in the nitride semiconductor light-emitting element, it is possible to reduce the operating voltage and operating current while inhibiting waveguide loss, as described above. As stated above, by including Ag in P-side electrode 111, it is possible to reduce the thickness of P-type cladding layer 108 while inhibiting waveguide loss. Accordingly, since the total Al content in P-type cladding layer 108 can be reduced, the strain of P-type cladding layer 108 on substrate 101 can be reduced. Accordingly, it is possible to inhibit nitride semiconductor light-emitting element 100 from cracking due to strain from P-type cladding layer 108.

### Embodiment 2

First, a nitride semiconductor light-emitting element according to Embodiment 2 will be described. The nitride semiconductor light-emitting element according to the present embodiment differs from nitride semiconductor light-emitting element 100 according to Embodiment 1 mainly in regard to the configuration of the P-side light guide layer. Hereinafter, the nitride semiconductor light-emitting element according to the present embodiment will be described focusing mainly on differences from nitride semiconductor light-emitting element 100 according to Embodiment 1.

### [2-1. Overall Configuration]

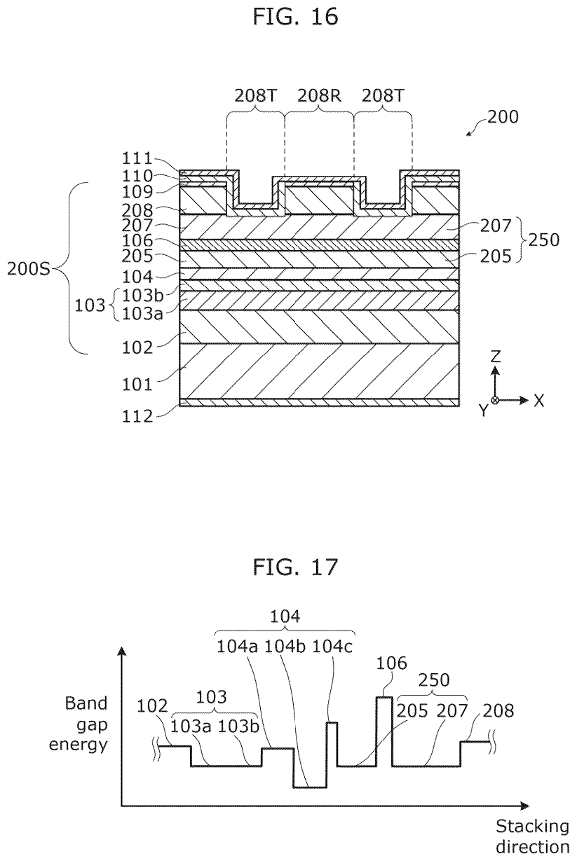

First, the overall configuration of the nitride semiconductor light-emitting element according to the present embodiment will be described with reference to FIG. 16 and FIG. 17. FIG. 16 is a schematic cross-sectional view of the overall configuration of nitride semiconductor light-emitting element 200 according to the present embodiment. FIG. 17 is a graph schematically illustrating a band gap energy distribution of semiconductor stack 200S of nitride semiconductor light-emitting element 200 according to the present embodiment.

As illustrated in FIG. 16, nitride semiconductor light-emitting element 200 according to the present embodiment includes substrate 101, semiconductor stack 200S, current blocking layer 110, P-side electrode 111, and N-side electrode 112. Semiconductor stack 200S includes N-type cladding layer 102, N-side guide layer 103, active layer 104, P-side guide layer 250, electron blocking layer 106, P-type cladding layer 208, and contact layer 109.

P-side guide layer 250 according to the present embodiment is a light guide layer disposed between active layer 104 and P-type cladding layer 208. In the present embodiment, P-side guide layer 250 includes upper P-side guide layer 207 and lower P-side guide layer 205.

Upper P-side guide layer 207 is a light guide layer disposed above electron blocking layer 106, and differs from upper P-side guide layer 107 according to Embodiment 1 in regard to thickness and impurity concentration distribution. In the present embodiment, upper P-side guide layer 207 is P-type Al_{0.03}Ga_{0.97}N layer that has a thickness of 130 nm. Upper P-side guide layer 207 is doped with Mg as a P-type impurity. Upper P-side guide layer 207 includes a first region having a thickness of 100 nm and a second region having a thickness of 30 nm and positioned above the first region. In the first region, the Mg concentration decreases from 4.0×10¹⁸ cm⁻³ to 2.0×10¹⁸ cm⁻³ as distance from active layer 104 increases. In the second region, the Mg concentration is constant at 2.0×10¹⁸ cm⁻³.

Lower P-side guide layer 205 is a light guide layer disposed between active layer 104 and electron blocking layer 106. In the present embodiment, as illustrated in FIG. 17, the average band gap energy of lower P-side guide layer 205 is less than or equal to the average band gap energy of upper P-side guide layer 207. Lower P-side guide layer 205 is, for example, an AlGaN layer or an AlInGaN layer. The average impurity concentration of lower P-side guide layer 205 is less than or equal to 1×10¹⁸ cm⁻³. Lower P-side guide layer 205 is, for example, a P-type Al_{0.03}Ga_{0.97}N layer that has a thickness of 60 nm, or a P-type Al_{0.02}Ga_{0.98}N layer that has a thickness of 60 nm. Note that FIG. 17 illustrates a band gap energy distribution when lower P-side guide layer 205 is a P-type Al_{0.03}Ga_{0.97}N layer.

P-type cladding layer 208 differs from P-type cladding layer 108 according to Embodiment 1 in regard to the impurity concentration distribution. In the present embodiment, P-type cladding layer 208 is a P-type Al_{0.065}Ga_{0.935}N layer that has a thickness of 450 nm. P-type cladding layer 208 is doped with Mg as a P-type impurity. P-type cladding layer 208 includes a first region having a thickness of 150 nm, a second region having a thickness of 100 nm and positioned above the first region, and a third region having a thickness of 200 nm and positioned above the second region. In the first region, the Mg concentration is constant at 2.0×10¹⁸ cm⁻³. In the second region, the Mg concentration increases from 2.0×10¹⁸ cm⁻³ to 1.0×10¹⁹ cm⁻³ as distance from active layer 104 increases. In the third region, the Mg concentration is constant at 1.0×10¹⁹ cm⁻³.

P-type cladding layer 208 includes ridge 208R and trench 208T, just like P-type cladding layer 108 according to Embodiment 1.

In the present embodiment, P-side guide layer 250 includes lower P-side guide layer 205 disposed between active layer 104 and electron blocking layer 106, thereby making it possible to distance electron blocking layer 106, which has a high impurity concentration, from active layer 104. Accordingly, since it is possible to reduce free carrier loss in electron blocking layer 106, it is possible to reduce the waveguide loss of nitride semiconductor light-emitting element 200.

In the present embodiment, the average band gap energy of lower P-side guide layer 205 is less than or equal to the average band gap energy of upper P-side guide layer 207. Stated differently, the average refractive index of lower P-side guide layer 205 is greater than or equal to the average refractive index of upper P-side guide layer 207. Accordingly, since it is possible to dispose lower P-side guide layer 205, which has a higher refractive index than upper P-side guide layer 207, in the vicinity of active layer 104, it becomes possible to make the distance from active layer 104 to the peak position of the light intensity distribution in the stacking direction shorter than the distance from active layer 104 to upper P-side guide layer 207. Accordingly, it becomes possible to increase the optical confinement factor.

In the present embodiment, the average impurity concentration of lower P-side guide layer 205 is less than or equal to 1×10¹⁸ cm⁻³. Accordingly, since it is possible to reduce free carrier loss in lower P-side guide layer 205 close to active layer 104, it is possible to reduce the waveguide loss of nitride semiconductor light-emitting element 200.

According to the present embodiment, when lower P-side guide layer 205 is a P-type Al_{0.03}Ga_{0.97}N layer with a thickness of 60 nm (i.e., when the average band gap energy of lower P-side guide layer 205 is equal to the average band gap energy of upper P-side guide layer 207), it has been confirmed from simulation results similar to the above simulation that it is possible to achieve nitride semiconductor light-emitting element 200 that has an optical confinement factor of 3.35%, effective refractive index difference ΔN of 19.2×10⁻³, a waveguide loss of 13.3 cm⁻¹, and a peak position of light intensity distribution in the stacking direction of 5.68 nm (i.e., the peak position is within well layer 104b).

Moreover, when lower P-side guide layer 205 is P-type Al_{0.02}Ga_{0.98}N layer with a thickness of 60 nm (i.e., when the average band gap energy of lower P-side guide layer 205 is less than the average band gap energy of upper P-side guide layer 207), it has been confirmed that it is possible to achieve nitride semiconductor light-emitting element 200 that has an optical confinement factor of 3.76%, effective refractive index difference ΔN of 20.4×10⁻³, a waveguide loss of 10.6 cm⁻¹, and a peak position of light intensity distribution in the stacking direction of 56.1 nm.

As a comparative example, a simulation was also performed for a nitride semiconductor light-emitting element in which the average band gap energy of the lower P-side guide layer is greater than the average band gap energy of the upper P-side guide layer. This simulation was performed for a nitride semiconductor light-emitting element in which the lower P-side guide layer is a P-type Al_{0.04}Ga_{0.96}N layer having a thickness of 60 nm (average Mg concentration of 1×10¹⁸ cm⁻³), and the upper P-side guide layer is a P-type Al_{0.03}Ga_{0.97}N layer having a thickness of 130 nm (Mg concentration distribution is the same as that of upper P-side guide layer 207). A nitride semiconductor light-emitting element according to such a comparative example has an optical confinement factor of 2.94%, effective refractive index difference ΔN of 18.1×10⁻³, a waveguide loss of 16.9 cm⁻¹, and a peak position of a light intensity distribution in the stacking direction that is 142.6 nm. Thus, it has been confirmed that nitride semiconductor light-emitting element 200 according to the present embodiment shows improvement in all characteristics compared to the nitride semiconductor light-emitting element according to the comparative example.

### [2-2. Variation 1]

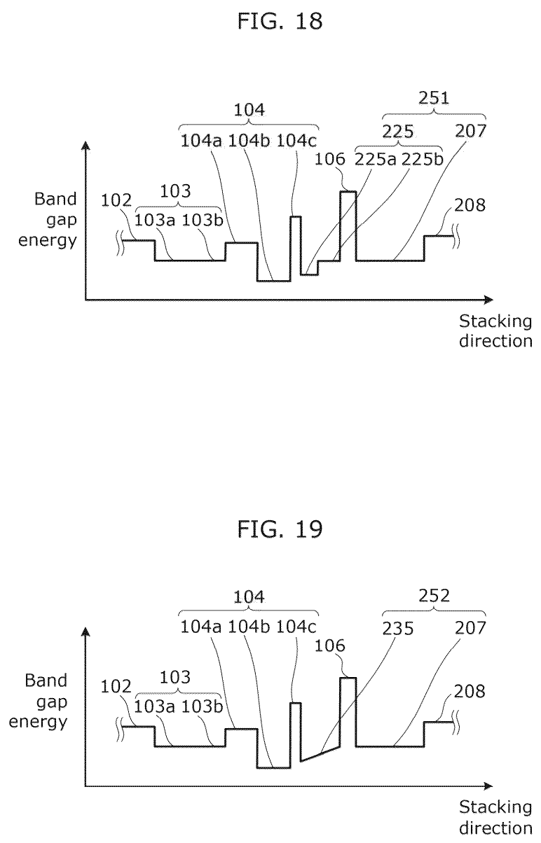

Next, a nitride semiconductor light-emitting element according to Variation 1 of the present embodiment will be described. The nitride semiconductor light-emitting element according to the present variation differs from nitride semiconductor light-emitting element 200 according to the present embodiment in regard to the configuration of the P-side guide layer, and is identical in the other aspects. Hereinafter, the nitride semiconductor light-emitting element according to the present variation will be described with reference to FIG. 18, focusing mainly on the differences from nitride semiconductor light-emitting element 200 according to the present embodiment. FIG. 18 is a graph schematically illustrating a band gap energy distribution of a semiconductor stack of the nitride semiconductor light-emitting element according to the present variation.

As illustrated in FIG. 18, the semiconductor stack of the nitride semiconductor light-emitting element according to the present variation includes N-type cladding layer 102, N-side guide layer 103, active layer 104, electron blocking layer 106, P-side guide layer 251, and P-type cladding layer 208. Although not illustrated in FIG. 18, the semiconductor stack according to the present variation further includes contact layer 109, just like semiconductor stack 200S according to the present embodiment.

P-side guide layer 251 according to the present variation is a light guide layer disposed between active layer 104 and P-type cladding layer 208, and includes upper P-side guide layer 207 and lower P-side guide layer 225.

Lower P-side guide layer 225 includes first lower P-side guide layer 225a and second lower P-side guide layer 225b that is disposed above first lower P-side guide layer 225a. The average band gap energy of first lower P-side guide layer 225a is less than the average band gap energy of second lower P-side guide layer 225b. Stated differently, the average refractive index of first lower P-side guide layer 225a is greater than the average refractive index of second lower P-side guide layer 225b. First lower P-side guide layer 225a is, for example, a GaN layer, an AlGaN layer, or an AlInGaN layer. Second lower P-side guide layer 225b is, for example, an AlGaN layer or an AlInGaN layer. The average impurity concentration of first lower P-side guide layer 225a and second lower P-side guide layer 225b is less than or equal to 1×10¹⁸ cm³.

As described above, in the nitride semiconductor light-emitting element according to the present variation, lower P-side guide layer 225 includes, in a region close to active layer 104, first lower P-side guide layer 225a having a high refractive index. This makes it possible to move the peak position of the light intensity distribution closer to active layer 104. Accordingly, it is possible to achieve a high optical confinement factor and low waveguide loss.

Due to the presence of an interface between first lower P-side guide layer 225a and second lower P-side guide layer 225b, which have different compositions from each other, it is possible to inhibit impurity diffusion from the P-type layer to active layer 104, making it possible to inhibit degradation of active layer 104.

Here, by using a GaN layer as first lower P-side guide layer 225a, compared to using an AlGaN layer, the refractive index can be increased while reducing the tensile strain associated with lattice mismatch between first lower P-side guide layer 225a and substrate 101. As a result, it is possible to move the peak position of the light intensity distribution closer to active layer 104 while inhibiting the occurrence of lattice defects.

By using AlInGaN as first lower P-side guide layer 225a, compared to using an AlGaN layer, the refractive index can be increased while reducing the tensile strain associated with lattice mismatch between first lower P-side guide layer 225a and substrate 101. As a result, it is possible to move the peak position of the light intensity distribution closer to active layer 104 while inhibiting the occurrence of lattice defects.

By causing the average impurity concentration of first lower P-side guide layer 225a and second lower P-side guide layer 225b to be less than or equal to 1×10¹⁸ cm⁻³, it is possible to reduce free carrier loss in lower P-side guide layer 225. Accordingly, it is possible to reduce the waveguide loss of the nitride semiconductor light-emitting element.

### [2-3. Variation 2]

Next, a nitride semiconductor light-emitting element according to Variation 2 of the present embodiment will be described. The nitride semiconductor light-emitting element according to the present variation differs from nitride semiconductor light-emitting element 200 according to the present embodiment in regard to the configuration of the P-side guide layer, and is identical in the other aspects. Hereinafter, the nitride semiconductor light-emitting element according to the present variation will be described with reference to FIG. 19, focusing mainly on the differences from nitride semiconductor light-emitting element 200 according to the present embodiment. FIG. 19 is a graph schematically illustrating a band gap energy distribution of a semiconductor stack of the nitride semiconductor light-emitting element according to the present variation.

As illustrated in FIG. 19, the semiconductor stack of the nitride semiconductor light-emitting element according to the present variation includes N-type cladding layer 102, N-side guide layer 103, active layer 104, electron blocking layer 106, P-side guide layer 252, and P-type cladding layer 208. Although not illustrated in FIG. 19, the semiconductor stack according to the present variation further includes contact layer 109, just like semiconductor stack 200S according to the present embodiment.

P-side guide layer 252 according to the present variation is a light guide layer disposed between active layer 104 and P-type cladding layer 208, and includes upper P-side guide layer 207 and lower P-side guide layer 235.

Lower P-side guide layer 235 is a light guide layer disposed between active layer 104 and electron blocking layer 106. The band gap energy of lower P-side guide layer 235 increases with proximity to electron blocking layer 106. Stated differently, the refractive index of lower P-side guide layer 235 decreases with proximity to electron blocking layer 106. Lower P-side guide layer 235 is, for example, a GaN layer, an AlGaN layer, or an AlInGaN layer. For example, the Al composition ratio of lower P-side guide layer 235 may increase with proximity to electron blocking layer 106. The average impurity concentration of lower P-side guide layer 235 is less than or equal to 1×10¹⁸ cm⁻³.

As described above, in the nitride semiconductor light-emitting element according to the present variation, the refractive index of lower P-side guide layer 235 increases with proximity to active layer 104. By increasing the refractive index in the region of lower P-side guide layer 235 close to active layer 104 in this way, it is possible to move the peak position of the light intensity distribution closer to active layer 104. Accordingly, it is possible to achieve a high optical confinement factor and low waveguide loss.

By causing the average impurity concentration of lower P-side guide layer 235 to be less than or equal to 1×10¹⁸ cm⁻³, it is possible to reduce free carrier loss in lower P-side guide layer 235. Accordingly, it is possible to reduce the waveguide loss of the nitride semiconductor light-emitting element.

### Embodiment 3

First, a nitride semiconductor light-emitting element according to Embodiment 3 will be described. The nitride semiconductor light-emitting element according to the present embodiment differs from nitride semiconductor light-emitting element 100 according to Embodiment 1 mainly in regard to the configuration of the P-side light guide layer. Hereinafter, the nitride semiconductor light-emitting element according to the present embodiment will be described focusing mainly on differences from nitride semiconductor light-emitting element 100 according to Embodiment 1.

### [3-1. Overall Configuration]

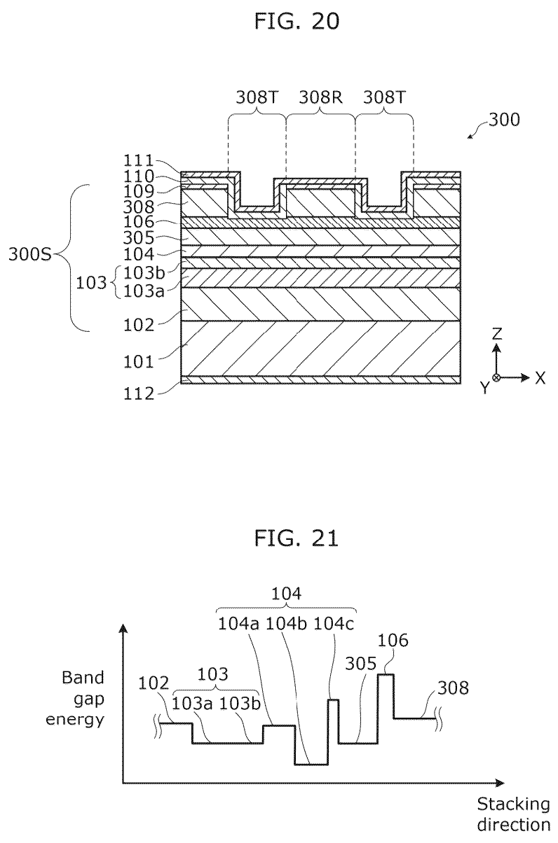

First, the overall configuration of the nitride semiconductor light-emitting element according to the present embodiment will be described with reference to FIG. 20 and FIG. 21. FIG. 20 is a schematic cross-sectional view of the overall configuration of nitride semiconductor light-emitting element 300 according to the present embodiment. FIG. 21 is a graph schematically illustrating a band gap energy distribution of semiconductor stack 300S of nitride semiconductor light-emitting element 300 according to the present embodiment.

As illustrated in FIG. 20, nitride semiconductor light-emitting element 300 according to the present embodiment includes substrate 101, semiconductor stack 300S, current blocking layer 110, P-side electrode 111, and N-side electrode 112. Semiconductor stack 300S includes N-type cladding layer 102, N-side guide layer 103, active layer 104, lower P-side guide layer 305, electron blocking layer 106, P-type cladding layer 308, and contact layer 109.

Lower P-side guide layer 305 according to the present embodiment is one example of a light guide layer included in the P-side guide layer disposed between active layer 104 and P-type cladding layer 308. Lower P-side guide layer 305 is a nitride semiconductor layer containing Al. In the present embodiment, the P-side guide layer includes lower P-side guide layer 305 disposed between active layer 104 and electron blocking layer 106. The average band gap energy of lower P-side guide layer 305 is less than the average band gap energy of P-type cladding layer 308.

Lower P-side guide layer 305 is, for example, an AlGaN layer or an AlInGaN layer. The average impurity concentration of lower P-side guide layer 305 is less than or equal to 1×10¹⁸ cm⁻³. Lower P-side guide layer 305 is, for example, a P-type Al_{0.02}Ga_{0.98}N layer that has a thickness of 60 nm.

P-type cladding layer 308 differs from P-type cladding layer 108 according to Embodiment 1 in regard to the impurity concentration distribution. In the present embodiment, P-type cladding layer 308 is a P-type Al_{0.065}Ga_{0.935}N layer that has a thickness of 450 nm. P-type cladding layer 308 is doped with Mg as a P-type impurity. P-type cladding layer 308 includes a first region having a thickness of 100 nm, a second region having a thickness of 180 nm and positioned above the first region, a third region having a thickness of 100 nm and positioned above the second region, and a fourth region having a thickness of 70 nm and positioned above the third region. In the first region, the Mg concentration decreases from 4.0×10¹⁸ cm⁻³ to 2.0×10¹⁸ cm⁻³ as distance from active layer 104 increases. In the second region, the Mg concentration is constant at 2.0×10¹⁸ cm⁻³. In the third region, the Mg concentration increases from 2.0×10¹⁸ cm⁻³ to 1.0×10¹⁹ cm⁻³ as distance from active layer 104 increases. In the fourth region, the Mg concentration is constant at 1.0×10¹⁹ cm⁻³.

P-type cladding layer 308 includes ridge 308R and trench 308T, just like P-type cladding layer 108 according to Embodiment 1.

In the present embodiment, the P-side guide layer includes lower P-side guide layer 305 disposed between active layer 104 and electron blocking layer 106, thereby making it possible to distance electron blocking layer 106, which has a high impurity concentration, from active layer 104. Accordingly, since it is possible to reduce free carrier loss in electron blocking layer 106, it is possible to reduce the waveguide loss of nitride semiconductor light-emitting element 300.

In the present embodiment, the average impurity concentration of lower P-side guide layer 305 is less than or equal to 1×10¹⁸ cm⁻³. Accordingly, since it is possible to reduce free carrier loss in lower P-side guide layer 305 close to active layer 104, it is possible to reduce the waveguide loss of nitride semiconductor light-emitting element 300.

According to the present embodiment, it has been confirmed from simulation results similar to the above simulation that it is possible to achieve nitride semiconductor light-emitting element 300 that has an optical confinement factor of 3.84%, effective refractive index difference ΔN of 18.8×10⁻³, a waveguide loss of 18.8 cm⁻¹, and a peak position of light intensity distribution in the stacking direction of −0.16 nm (i.e., the peak position is within N-side barrier layer 104a).

### [3-2. Variation 1]

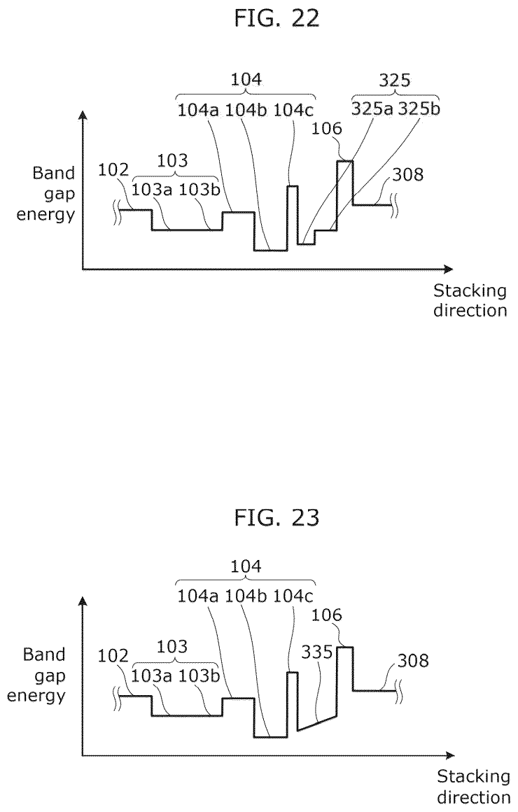

Next, a nitride semiconductor light-emitting element according to Variation 1 of the present embodiment will be described. The nitride semiconductor light-emitting element according to the present variation differs from nitride semiconductor light-emitting element 300 according to the present embodiment in regard to the configuration of the P-side guide layer, and is identical in the other aspects. Hereinafter, the nitride semiconductor light-emitting element according to the present variation will be described with reference to FIG. 22, focusing mainly on the differences from nitride semiconductor light-emitting element 300 according to the present embodiment. FIG. 22 is a graph schematically illustrating a band gap energy distribution of a semiconductor stack of the nitride semiconductor light-emitting element according to the present variation.

As illustrated in FIG. 22, the semiconductor stack of the nitride semiconductor light-emitting element according to the present variation includes N-type cladding layer 102, N-side guide layer 103, active layer 104, lower P-side guide layer 325, electron blocking layer 106, and P-type cladding layer 308. Although not illustrated in FIG. 22, the semiconductor stack according to the present variation further includes contact layer 109, just like semiconductor stack 300S according to the present embodiment.

Lower P-side guide layer 325 includes first lower P-side guide layer 325a and second lower P-side guide layer 325b that is disposed above first lower P-side guide layer 325a. The average band gap energy of first lower P-side guide layer 325a is less than the average band gap energy of second lower P-side guide layer 325b. Stated differently, the average refractive index of first lower P-side guide layer 325a is greater than the average refractive index of second lower P-side guide layer 325b. First lower P-side guide layer 325a is, for example, a GaN layer, an AlGaN layer, or an AlInGaN layer. Second lower P-side guide layer 325b is, for example, an AlGaN layer or an AlInGaN layer. The average impurity concentration of first lower P-side guide layer 325a and second lower P-side guide layer 325b is less than or equal to 1×10¹⁸ cm⁻³.

As described above, in the nitride semiconductor light-emitting element according to the present variation, lower P-side guide layer 325 includes, in a region close to active layer 104, first lower P-side guide layer 325a having a high refractive index. This makes it possible to move the peak position of the light intensity distribution closer to active layer 104. Accordingly, it is possible to achieve a high optical confinement factor and low waveguide loss.

Due to the presence of an interface between first lower P-side guide layer 325a and second lower P-side guide layer 325b, which have different compositions from each other, it is possible to inhibit impurity diffusion from the P-type layer to active layer 104, making it possible to inhibit degradation of active layer 104.

Here, by using a GaN layer as first lower P-side guide layer 325a, compared to using an AlGaN layer, the refractive index can be increased while reducing the tensile strain associated with lattice mismatch between first lower P-side guide layer 325a and substrate 101. As a result, it is possible to move the peak position of the light intensity distribution closer to active layer 104 while inhibiting the occurrence of lattice defects.

By using an AlInGaN layer as first lower P-side guide layer 325a, compared to using an AlGaN layer, the refractive index can be increased while reducing the tensile strain associated with lattice mismatch between first lower P-side guide layer 325a and substrate 101. As a result, it is possible to move the peak position of the light intensity distribution closer to active layer 104 while inhibiting the occurrence of lattice defects.

By causing the average impurity concentration of first lower P-side guide layer 325a and second lower P-side guide layer 325b to be less than or equal to 1×10¹⁸ cm⁻³, it is possible to reduce free carrier loss in lower P-side guide layer 325. Accordingly, it is possible to reduce the waveguide loss of the nitride semiconductor light-emitting element.

### [3-3. Variation 2]

Next, a nitride semiconductor light-emitting element according to Variation 2 of the present embodiment will be described. The nitride semiconductor light-emitting element according to the present variation differs from nitride semiconductor light-emitting element 300 according to the present embodiment in regard to the configuration of the P-side guide layer, and is identical in the other aspects. Hereinafter, the nitride semiconductor light-emitting element according to the present variation will be described with reference to FIG. 23, focusing mainly on the differences from nitride semiconductor light-emitting element 300 according to the present embodiment. FIG. 23 is a graph schematically illustrating a band gap energy distribution of a semiconductor stack of the nitride semiconductor light-emitting element according to the present variation.

As illustrated in FIG. 23, the semiconductor stack of the nitride semiconductor light-emitting element according to the present variation includes N-type cladding layer 102, N-side guide layer 103, active layer 104, lower P-side guide layer 335, electron blocking layer 106, and P-type cladding layer 308. Although not illustrated in FIG. 23, the semiconductor stack according to the present variation further includes contact layer 109, just like semiconductor stack 300S according to the present embodiment.

Lower P-side guide layer 335 is a light guide layer disposed between active layer 104 and electron blocking layer 106. The band gap energy of lower P-side guide layer 335 increases with proximity to electron blocking layer 106. Stated differently, the refractive index of lower P-side guide layer 335 decreases with proximity to electron blocking layer 106. Lower P-side guide layer 335 is, for example, a GaN layer, an AlGaN layer, or an AlInGaN layer. For example, the Al composition ratio of lower P-side guide layer 335 may increase with proximity to electron blocking layer 106. The average impurity concentration of lower P-side guide layer 335 is less than or equal to 1×10¹⁸ cm⁻³.

As described above, in the nitride semiconductor light-emitting element according to the present variation, the refractive index of lower P-side guide layer 335 increases with proximity to active layer 104. By increasing the refractive index in the region of lower P-side guide layer 335 close to active layer 104 in this way, it is possible to move the peak position of the light intensity distribution closer to active layer 104. Accordingly, it is possible to achieve a high optical confinement factor and low waveguide loss.

By causing the average impurity concentration of lower P-side guide layer 335 to be less than or equal to 1×10¹⁸ cm⁻³, it is possible to reduce free carrier loss in lower P-side guide layer 335. Accordingly, it is possible to reduce the waveguide loss of the nitride semiconductor light-emitting element.

### Other Variations

Although the nitride semiconductor light-emitting element according to the present disclosure has been described above based on embodiments and variations thereof, the present disclosure is not limited to the embodiments and variations thereof.

For example, although the above embodiments and variations thereof describe a semiconductor light-emitting element that emits ultraviolet light, the semiconductor light-emitting element according to the present disclosure is not limited to a semiconductor light-emitting element that emits ultraviolet light. The characteristic configuration of the semiconductor light-emitting element according to the present disclosure can be applied to semiconductor light-emitting elements that emit light in wavelength bands such as visible light and infrared light, for example, and can achieve effects similar to those of the above embodiments and variations thereof.

Although the nitride semiconductor light-emitting element is exemplified as a semiconductor laser element in the above embodiments and variations thereof, the nitride semiconductor light-emitting element is not limited to a semiconductor laser element. For example, the nitride semiconductor light-emitting element may be a superluminescent diode. In this case, the reflectance of an end face of the semiconductor stack included in the nitride semiconductor light-emitting element relative to emission light from the semiconductor stack may be at most 0.1%. It is possible to achieve such a reflectance by, for example, forming an antireflection film including a dielectric multilayer film etc., on the end face. Alternatively, by forming a tilted stripe structure in which a ridge that serves as a waveguide intersects a front end face at at least a 5-degree tilt from a normal direction of the front end face, it is possible to cause the percentage of components that become guided light by guided light reflected from the front end face being combined again with the waveguide to be a small value of at most 0.1%.

Although each P-type cladding layer is a layer having a uniform Al composition ratio in the above embodiments and variations thereof, the configuration of the P-type cladding layer is not limited to this example. For example, the P-type cladding layer may have a superlattice structure in which AlGaN layers and GaN layers are alternately stacked.

Although the active layer has a single quantum well structure in the above embodiments and variations thereof, the active layer may have a multiple quantum well structure. In such cases, the same advantageous effects as those of the above embodiments and variations thereof can be achieved by applying the configuration of the N-side barrier layer according to the above embodiments and variations thereof to the barrier layer closest to the N-type cladding layer among the barrier layers of the multiple quantum well structure, and by applying the configuration of the P-side barrier layer according to the above embodiments and variations thereof to the barrier layer closest to the P-type cladding layer among the barrier layers of the multiple quantum well structure.

Embodiments arrived at by a person skilled in the art making various modifications to any one of the above embodiments as well as embodiments realized by arbitrarily combining elements and functions in the above embodiments which do not depart from the essence of the present disclosure are included in the present disclosure.

For example, the configuration of P-side barrier layer 124c according to the variation of Embodiment 1 may be applied to the P-side barrier layer of Embodiment 2 and Embodiment 3, as well as their variations.

### INDUSTRIAL APPLICABILITY

The nitride semiconductor light-emitting element according to the present disclosure is applicable as, for example, a high-output and high-efficiency light source, particularly as a light source for exposure devices and processing machines.

1. A nitride semiconductor light-emitting element comprising:
an N-type cladding layer;
an N-side guide layer disposed above the N-type cladding layer;
an active layer disposed above the N-side guide layer;
a P-type cladding layer disposed above the active layer; and
a P-side guide layer and an electron blocking layer that are disposed between the active layer and the P-type cladding layer, wherein
the N-type cladding layer, the N-side guide layer, the P-side guide layer, the electron blocking layer, and the P-type cladding layer contain Al,
the active layer includes an N-side barrier layer, a well layer disposed above the N-side barrier layer, and a P-side barrier layer disposed above the well layer,
an average band gap energy of the P-side barrier layer is greater than an average band gap energy of the N-side barrier layer, and
a thickness of the P-side barrier layer is less than a thickness of the N-side barrier layer.

2. A nitride semiconductor light-emitting element comprising:
an N-type cladding layer;
an N-side guide layer disposed above the N-type cladding layer;
an active layer disposed above the N-side guide layer;
a P-type cladding layer disposed above the active layer; and
a P-side guide layer and an electron blocking layer that are disposed between the active layer and the P-type cladding layer, wherein
the N-type cladding layer, the electron blocking layer, and the P-type cladding layer contain Al,
the active layer includes an N-side barrier layer, a well layer disposed above the N-side barrier layer, and a P-side barrier layer disposed above the well layer,
an average band gap energy of the P-side barrier layer is greater than an average band gap energy of the N-side barrier layer,
a thickness of the P-side barrier layer is less than a thickness of the N-side barrier layer,
the P-side guide layer includes a lower P-side guide layer disposed between the active layer and the electron blocking layer, and
a band gap energy of the lower P-side guide layer increases with proximity to the electron blocking layer.

3. The nitride semiconductor light-emitting element according to claim 2, wherein
the lower P-side guide layer includes a first lower P-side guide layer and a second lower P-side guide layer disposed above the first lower P-side guide layer, and
an average band gap energy of the first lower P-side guide layer is less than an average band gap energy of the second lower P-side guide layer.

4. The nitride semiconductor light-emitting element according to claim 2, wherein
the P-side guide layer includes an upper P-side guide layer disposed above the electron blocking layer, and
an average band gap energy of the lower P-side guide layer is less than or equal to an average band gap energy of the upper P-side guide layer.

5. A nitride semiconductor light-emitting element comprising:
an N-type cladding layer;
an N-side guide layer disposed above the N-type cladding layer;
an active layer disposed above the N-side guide layer;
a P-type cladding layer disposed above the active layer; and
a P-side guide layer and an electron blocking layer that are disposed between the active layer and the P-type cladding layer, wherein
the N-type cladding layer, the electron blocking layer, and the P-type cladding layer contain Al,
the active layer includes an N-side barrier layer, a well layer disposed above the N-side barrier layer, and a P-side barrier layer disposed above the well layer,
an average band gap energy of the P-side barrier layer is greater than an average band gap energy of the N-side barrier layer,
a thickness of the P-side barrier layer is less than a thickness of the N-side barrier layer,
the P-side guide layer includes a lower P-side guide layer disposed between the active layer and the electron blocking layer,
the lower P-side guide layer includes a first lower P-side guide layer and a second lower P-side guide layer disposed above the first lower P-side guide layer, and
an average band gap energy of the first lower P-side guide layer is less than an average band gap energy of the second lower P-side guide layer.

6. The nitride semiconductor light-emitting element according to claim 5, wherein
the P-side guide layer includes an upper P-side guide layer disposed above the electron blocking layer, and
an average band gap energy of the lower P-side guide layer is less than or equal to an average band gap energy of the upper P-side guide layer.

7. The nitride semiconductor light-emitting element according to claim 1, wherein
the P-side guide layer includes an upper P-side guide layer disposed above the electron blocking layer.

8. The nitride semiconductor light-emitting element according to claim 7, wherein
an average band gap energy of the upper P-side guide layer is less than an average band gap energy of the P-type cladding layer.

9. The nitride semiconductor light-emitting element according to claim 7, wherein
the P-side guide layer includes a lower P-side guide layer disposed between the active layer and the electron blocking layer, and
an average band gap energy of the lower P-side guide layer is less than or equal to an average band gap energy of the upper P-side guide layer.

10. The nitride semiconductor light-emitting element according to claim 1, wherein
the P-side guide layer includes a lower P-side guide layer disposed between the active layer and the electron blocking layer.

11. The nitride semiconductor light-emitting element according to claim 10, wherein
an average band gap energy of the lower P-side guide layer is less than an average band gap energy of the P-type cladding layer.

12. The nitride semiconductor light-emitting element according to claim 9, wherein
the lower P-side guide layer includes a first lower P-side guide layer and a second lower P-side guide layer disposed above the first lower P-side guide layer, and
an average band gap energy of the first lower P-side guide layer is less than an average band gap energy of the second lower P-side guide layer.

13. The nitride semiconductor light-emitting element according to claim 9, wherein
a band gap energy of the lower P-side guide layer increases with proximity to the electron blocking layer.

14. The nitride semiconductor light-emitting element according to claim 9, wherein
the lower P-side guide layer is an AlGaN layer or an AlInGaN layer, and
an average impurity concentration of the lower P-side guide layer is less than or equal to 1×10¹⁸ cm⁻³.

15. The nitride semiconductor light-emitting element according to claim 12, wherein
the first lower P-side guide layer is a GaN layer, an AlGaN layer, or an AlInGaN layer,
the second lower P-side guide layer is an AlGaN layer or an AlInGaN layer, and
an average impurity concentration of the first lower P-side guide layer and an average impurity concentration of the second lower P-side guide layer is less than or equal to 1×10¹⁸ cm⁻³.

16. The nitride semiconductor light-emitting element according to claim 13, wherein
the lower P-side guide layer is a GaN layer, an AlGaN layer, or an AlInGaN layer, and
an average impurity concentration of the lower P-side guide layer is less than or equal to 1×10¹⁸ cm⁻³.

17. The nitride semiconductor light-emitting element according to claim 1, wherein
the average band gap energy of the N-side barrier layer is less than an average band gap energy of the N-type cladding layer.

18. The nitride semiconductor light-emitting element according to claim 1, wherein
the average band gap energy of the P-side barrier layer is less than an average band gap energy of the electron blocking layer.

19. The nitride semiconductor light-emitting element according to claim 1, wherein
the P-side barrier layer includes a first P-side barrier layer and a second P-side barrier layer disposed above the first P-side barrier layer, and
an average band gap energy of the second P-side barrier layer is greater than an average band gap energy of the first P-side barrier layer.

20. The nitride semiconductor light-emitting element according to claim 19, wherein
the average band gap energy of the second P-side barrier layer is less than an average band gap energy of the electron blocking layer.

21. The nitride semiconductor light-emitting element according to claim 19, wherein
the second P-side barrier layer is an AlGaN layer or an AlInGaN layer, and
an average impurity concentration of the second P-side barrier layer is less than or equal to 1×10¹⁸ cm⁻³.

22. The nitride semiconductor light-emitting element according to claim 1, further comprising:
a P-side electrode disposed above the P-type cladding layer, wherein
the P-side electrode contains Ag.
